(19) United States
(12) Patent Application Publication
(10) Pub. No.: US 2011/0042791 A1
(43) Pub. Date: Feb. 24, 2011

(54) METHOD FOR TREATING AN OXYGEN-CONTAINING SEMICONDUCTOR WAFER, AND SEMICONDUCTOR COMPONENT

(75) Inventors: Hans-Joachim Schulze, Taufkirchen (DE); Helmut Strack, Muenchen (DE); Anton Mauder, Kolbermoor (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AUSTRIA AG, Villach (AT)

(21) Appl. No.: 12/161,472

(22) PCT Filed: Jan. 19, 2007
(86) PCT No.: PCT/EP07/00475

§ 371 Date: Sep. 21, 2010

(30) Foreign Application Priority Data
Jan. 20, 2006 (DE) 10 2006 002 903.8
Mar. 29, 2006 (DE) 10 2006 014 639.5
Sep. 4, 2006 (DE) 10 2006 041 402.0

(51) Int. Cl. H01L 29/08; H01L 21/26; H01L 21/322

(52) U.S. Cl. 257/655; 438/530; 438/473; 257/E21.328; 257/E21.318; 257/E29.04

(57) ABSTRACT

A method for treating an oxygen-containing semiconductor wafer, and semiconductor component. One embodiment provides a first side, a second side opposite the first side. A first semiconductor region adjoins the first side. A second semiconductor region adjoins the second side. The second side of the wafer is irridated such that lattice vacancies arise in the second semiconductor region. A first thermal process is carried out the duration of which is chosen such that oxygen agglomerates form in the second semiconductor region and that lattice vacancies diffuse from the first semiconductor region into the second semiconductor region.

### TECHNICAL BACKGROUND

The present invention relates to a method for treating an oxygen-containing semiconductor wafer.

Known methods for producing semiconductor single crystals, e.g. silicon single crystals, which are required for the realization of semiconductor components, are the so-called float zone method (FZ method) or the Czochralski method (CZ method). Disk-like semiconductor wafers are cut off from the monocrystalline semiconductor rods produced by these methods and form the basis for the production of semiconductor components. The CZ method can be carried out more cost-effectively in comparison with the FZ method, but affords the disadvantage that the single crystal, owing to the production method, has a high oxygen concentration, which is typically in the range of a few 10¹⁷ atoms/cm³.

Thermal processes which occur during the methods for producing and processing the semiconductor wafers have the effect that the oxygen present in high concentration in the wafer forms so-called oxygen precipitates. These should be understood to mean oxygen agglomerates or oxygen-vacancy agglomerates in the semiconductor crystal. These precipitates act, inter alia, as guttering centers for heavy metal atoms which can pass into the wafer during the method for producing the components. If such precipitates are present in an active component zone of a semiconductor component, however, they lead to an impairment of the component properties by virtue of the fact that they act as recombination centers for free charge carriers and by virtue of the fact that they act as generation centers for charge carrier pairs, this last leading to an increase in the leakage current flowing during reverse operation of the component.

For the reasons mentioned above, CZ wafers, without further treatment, are of only limited suitability for the realization of power components having a dielectric strength of a few hundred volts. CZ wafers are suitable without further treatment for said components only as a semiconductor substrate to which further (oxygen-poor) semiconductor layers are applied by means of complicated and hence cost-intensive epitaxy methods, in which semiconductor layers the regions of a power component which take up a reverse voltage, for example the drift zone of a MOSFET or the n-type base of an IGBT, are realized.

There are various methods for preventing oxygen precipitates in regions of a CZ wafer that are near the surface, such that said regions can be utilized for the production of active component zones. At the same time, oxygen precipitates are deliberately produced in regions situated more deeply, which oxygen precipitates serve there as “intrinsic guttering centers” for, in particular undesirable, impurities introduced into the wafer, such as e.g. heavy metal atoms.

One known method for preventing oxygen precipitates in the regions of a wafer that are near the surface consists in reducing the oxygen concentration in said region of the wafer by virtue of oxygen atoms being outdiffused from the region of the wafer that is near the surface by means of a thermal process.

U.S. Pat. No. 6,849,119 B2 (Falster) describes a method in which a CZ semiconductor wafer is subjected to a thermal process in which the rear side of the wafer is exposed to a nitriding atmosphere and the front side of said wafer is exposed to a non-nitriding atmosphere. This thermal treatment leads to the production of crystal vacancies, wherein the maximum of a vacancy profile established lies nearer to the rear side than to the front side. The wafer is subsequently subjected to a further thermal treatment at temperatures of 800° C. and 1000° C., thus giving rise to oxygen precipitates in regions with a high vacancy concentration.

Further methods for treating a wafer with the aim of producing a low-precipitate semiconductor zone in a region of a wafer that adjoins a surface are described in U.S. Pat. No. 5,882,989 (Falster) or U.S. Pat. No. 5,994,761 (Falster).

EP 0769809 A1 (Schulze) describes a method for reducing the vacancy concentration in a wafer by virtue of interstitial silicon being injected into the wafer on account of an oxidation process.

Wondrak, W.: “Einsatz von Protonenbestrahlung in der Technologie der Leistungshalbleiter”, [“Use of proton irradiation in the technology of power semiconductors”], in: Archiv für Elektrotechnik, 1989, Volume 72, pages 133-140, describes a method for the n-type doping of a semiconductor material by proton irradiation and subsequently carrying out a thermal step.

### SUMMARY

It is an object of the present invention to provide a method for treating an oxygen-containing wafer serving for the production of semiconductor components, which prevents oxygen precipitates in a region of the wafer that is near the surface, and in which a zone having a high density of oxygen precipitates is produced preferably in a wafer region opposite the region near the surface.

This object is achieved by means of a method according to claims 1 and 55. The invention additionally relates to a vertical semiconductor component according to claim 50. The subclaims relate to advantageous configurations.

One exemplary embodiment of the method according to the invention for treating an oxygen-containing semiconductor wafer having a first side, a second side opposite the first side, a first semiconductor region adjoining the first side, and a second semiconductor region adjoining the second side, provides for irradiating the second side of the wafer with high-energy particles in order thereby to produce crystal defects—such as e.g. vacancies, double vacancies or vacancy/oxygen complexes—in the second semiconductor region of the wafer. A first thermal process is subsequently carried out, in which the wafer is heated to temperatures of between 700° C. and 1100° C. for a predetermined time duration.

During said first thermal process, e.g. higher-valency vacancy (V)—oxygen (O) complexes (e.g. O₂V complexes) form in the second semiconductor region, which has a high concentration of crystal defects and hence a high concentration of crystal lattice vacancies in comparison with the first semiconductor region. Said vacancy-oxygen complexes act as nucleation seeds to which further oxygen atoms or oxygen ions or else further vacancy/oxygen complexes are attached, thus giving rise to stable oxygen agglomerates in the second semiconductor region. The vacancy-oxygen complexes or the oxygen agglomerates furthermore act as guttering centers for impurities present in the semiconductor wafer, such as heavy metal atoms for example, and for lattice vacancies. This guttering effect of the vacancy-oxygen complexes and oxygen agglomerates present in the second semiconductor region furthermore leads to a diffusion of lattice vacancies from the first semiconductor region into the second semiconductor region, whereby the first semiconductor region is depleted of lattice vacancies. Owing to the absence of lattice vacancies in the first semiconductor region, no or only very few oxygen precipitates can form in this semiconductor region, whereby a semiconductor zone low in oxygen precipitates, a so-called “denuded zone”, arises in the first semiconductor region adjoining the first side. Such a semiconductor zone is referred to hereinafter as low-precipitate zone.

By means of the method explained, it is possible to achieve a significantly larger vertical extent of the zone substantially free of oxygen precipitates than in the case of known methods. This is suitable in particular for vertical power semiconductor components which are intended to have breakdown voltages of above 500 V and in which correspondingly large vertical dimensions of a component zone that takes up the reverse voltage, e.g. the drift zone in the case of a MOSFET, are therefore required.

The method explained for producing the low-precipitate zone furthermore leads to a more homogeneous low-precipitate zone in comparison with conventional methods. An implantation process leads, on account of the very small fluctuations of the implantation dose in a lateral direction, that is to say transversely with respect to the implantation direction, to a significantly more homogeneous distribution of the vacancy concentration in the lateral direction than, for example, a conventional RTA process (RTA=rapid thermal annealing) in a nitriding atmosphere. Moreover, an implantation process is insensitive toward thin “parasitic” layers present on the wafer surface, whereas such layers, in an RTA process that acts on the wafer surface, significantly influence the speeds of surface reactions and hence the production of vacancies.

The irradiation of the semiconductor body with high-energy particles for producing crystal defects, in particular for producing lattice vacancies, leads to a high concentration of lattice vacancies in the second semiconductor region, thus to a high concentration of oxygen precipitates in the second semiconductor region, since the vacancies considerably promote oxygen precipitation, that is to say the formation of such precipitates. Moreover, the high vacancy concentration in the second semiconductor region leads to a particularly effective outdiffusion of lattice vacancies from the first semiconductor region into the second semiconductor region. The lattice vacancies can be produced by the irradiation with high-energy particles with a high reproducibility within a wafer and from wafer to wafer, which represents a further advantage over known methods.

While only a vacancy concentration of between 10¹² and 10¹³ vacancies per cubic centimeter (cm³) can be achieved in a thermal process in a nitriding atmosphere, vacancy concentrations of more than 10¹⁸ vacancies per cm³ can be produced when the semiconductor body is irradiated with protons, for example, which leads to a considerable intensification of the desired effect. A further advantage of the present invention consists in the fact that through a corresponding choice of the irradiation energy and irradiation dose, in contrast to a method that uses nitriding steps for producing vacancies, virtually any desired vacancy distributions can be established in the semiconductor wafer; in particular, very high vacancy concentrations can be produced even in a relatively large depth of the semiconductor crystal.

The high-energy particles used for irradiation are, in particular, non-doping particles such as protons, noble gas ions, e.g. helium ions, neon ions or argon ions, or semiconductor ions, e.g. germanium ions or silicon ions. However, doping particles, such as phosphorous ions for example, are also suitable as high-energy particles for irradiating the semiconductor body with the aim of producing crystal defects. Since the penetration depth of the high-energy particles for a given irradiation energy should not be too small, however, protons or helium ions are preferably employed, which penetrate more deeply for a given energy than the heavier particles.

### BRIEF DESCRIPTION OF THE FIGURES

Exemplary embodiments of the present invention are explained in more detail below with reference to figures.

FIG. 1 illustrates a method according to the invention for treating a semiconductor wafer during different method steps.

FIG. 2 illustrates a modification of the method according to the invention elucidated with reference to FIG. 1.

FIG. 3 illustrates a method for producing an n-doped semiconductor zone in a low-precipitate semiconductor zone of a CZ semiconductor wafer.

FIG. 4 shows the semiconductor wafer after carrying out further method steps, in which an epitaxial layer is applied to a first side of the semiconductor wafer.

FIG. 5 shows in side view in cross section a power MOSFET or power IGBT realized in a semiconductor wafer treated according to the method according to the invention.

FIG. 6 shows in side view in cross section a power diode realized in a semiconductor wafer treated according to the method according to the invention.

### DETAILED DESCRIPTION OF THE FIGURES

In the figures, unless indicated otherwise, identical reference symbols designate identical wafer regions or component regions with the same meaning.

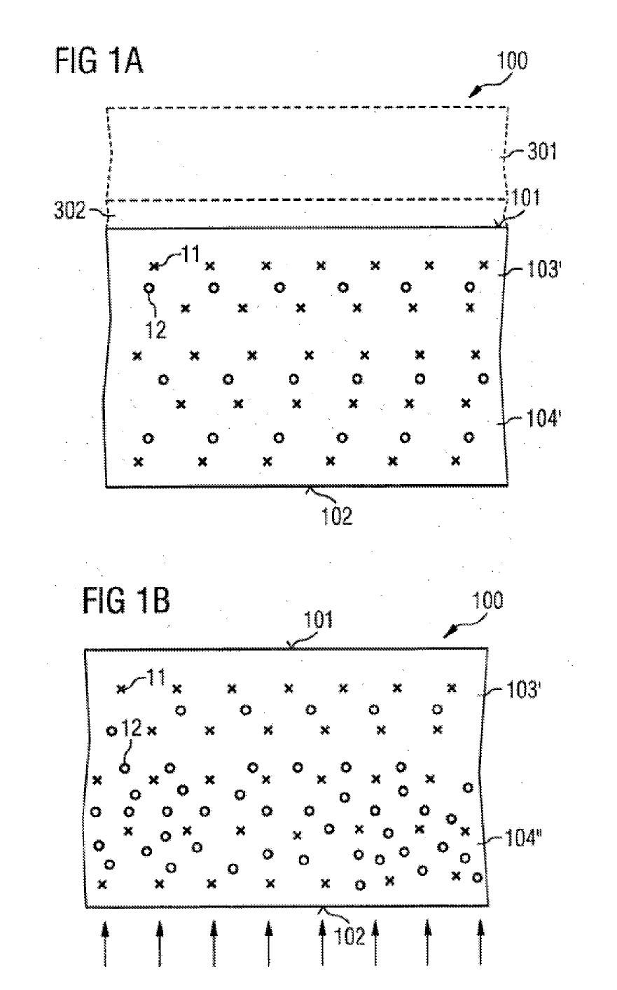

FIG. 1A schematically shows in side view in cross section an excerpt from an oxygen-containing semiconductor wafer 100. This wafer has been cut off from a single crystal produced by a crucible pulling method or Czochralski method and is referred to hereinafter as CZ wafer. The oxygen concentration of such a CZ wafer usually lies above 5·10¹⁷ atoms/cm³. The wafer can be undoped or can have a basic doping, in particular a homogeneous basic doping, for example an n-type basic doping, which is produced as early as in the course of pulling the single crystal during the Czochralski method. In particular, the wafer can have exclusively said basic doping at the beginning of the method, that is to say was not previously subjected to any implantation or diffusion processes—which are always associated with thermal processes—for producing further doped regions, nor was it is subjected to an implantation process by means of which initially only dopant atoms were implanted without the latter being activated by a thermal process.

The wafer 100 has a first side 101, which is referred to hereinafter as front side, and a second side 102, which is referred to hereinafter as rear side. Oxygen atoms present in the crystal lattice of the wafer are illustrated schematically by crosses and designated by the reference symbol 11 in FIG. 1A. Alongside oxygen atoms, the crystal lattice also inevitably contains vacancies and vacancy agglomerates after the conclusion of the Czochralski method, and these are illustrated schematically as circles and designated by the reference symbol 12 in FIG. 1A. A semiconductor region adjoining the front side 101 in a vertical direction of the wafer is referred to hereinafter as first semiconductor region 103′, while a region adjoining the rear side 102 in a vertical direction of the wafer 100 is referred to hereinafter as second semiconductor region 104′.

The aim is to produce a semiconductor zone low in oxygen precipitates or a precipitate-low semiconductor zone (denuded zone) in the first semiconductor region 103′ adjoining the front side 101.

For this purpose, referring to FIG. 1B, one exemplary embodiment of the method according to the invention provides for irradiating the wafer 100 with high-energy particles via its rear side 102 in order thereby to produce crystal defects, in particular lattice vacancies, in the second semiconductor region 104, such that an increased vacancy concentration is present in the second semiconductor region 104′ in comparison with the first semiconductor region 103. This semiconductor zone having an increased vacancy concentration is designated by the reference symbol 104″ in FIG. 1B. The vacancies produced by the irradiation with high-energy particles should be understood hereinafter to be in particular single vacancies (V), double vacancies (VV) and also vacancy-oxygen complexes (OV). However, higher-valancy vacancy-oxygen complexes or other crystal defects can also occur.

In particular non-doping particles such as protons, noble gas ions or semiconductor ions are suitable as particles for the irradiation of the wafer 100.

Production of the vacancies in the second semiconductor region 104 by means of the irradiation with high-energy particles is followed by a first thermal process, in which the wafer is heated to temperatures of between 700° C. and 1100° C. for a specific time duration. In this case, the temperature and duration of this thermal process are chosen such that vacancy-oxygen centers (O₂V centers) or else higher-valancy vacancy-oxygen complexes arise in the second semiconductor region 104″ having a high vacancy concentration. The thermal process can be configured in particular in such a way that at least two different temperatures are set temporally successively, said temperatures each being held for a predetermined time duration. In this case, the time durations of these individual “temperature plateaus” can be of identical length or else of different lengths.

The vacancy-oxygen centers produced by the irradiation and the thermal process act as nucleation seeds for oxygen precipitates, thus resulting in the formation of stable oxygen agglomerates in the second semiconductor region 104 during the first thermal process. The nucleation seeds and oxygen agglomerates additionally act as guttering centers for impurities, such as heavy metal atoms for example, which are present in the semiconductor wafer or diffuse into the semiconductor during subsequent high-temperature processes, and additionally act as guttering centers for lattice vacancies. This has the effect that, during the first thermal process, lattice vacancies diffuse from the first semiconductor region 103 into the second semiconductor region 104, whereby a low-vacancy semiconductor zone arises in the first semiconductor region 103. The depletion of the first semiconductor region 103 of vacancies counteracts an arising of oxygen precipitates in the first semiconductor region 103, such that, after the conclusion of the thermal process, the first semiconductor region 103′ forms a low-precipitate semiconductor zone, which is designated by the reference symbol 103 in FIG. 1C.

The nucleation seeds and oxygen agglomerates present in the second semiconductor region 104 are stable and are no longer resolved by subsequent thermal processes such as are employed for example during the production of semiconductor components on the basis of the wafer. Owing to the lack of vacancies present in the first semiconductor region 103, oxygen precipitates that would adversely influence the function of a semiconductor component, in particular of a power component, cannot form during such thermal processes in the first semiconductor region 103 since, in the absence of vacancies, precipitate formation becomes very unlikely and/or takes a very long time. Consequently, the low-precipitate semiconductor zone 103 of the wafer that is produced by means of the method explained is suitable in particular also for realizing active component zones, in particular those component zones which serve, in power semiconductor components, for taking up a reverse voltage of the component. In the case of vertical power semiconductor components, the second semiconductor region 104, which has a high precipitate density, can be removed after the end of the front side processes and the so-called rear side processes, which are required for completing the semiconductor component, can subsequently be carried out. In the case of lateral components, in which a current flow direction runs in a lateral direction of the semiconductor body, the second semiconductor region can also remain.

It should be pointed out that the irradiation of the semiconductor body with high-energy particles and the first thermal process for producing the vacancy-oxygen centers do not have to be effected in direct temporal succession. As will be explained below, there is in particular the possibility, before carrying out the process referred to previously as “first thermal process”, one or more thermal processes at a lower temperature, which serve for stabilizing the states established after the irradiation in the wafer.

The thermal processes succeeding the irradiation process can be dedicated thermal processes which are only carried out for forming the vacancy-oxygen centers or for stabilization. However, said thermal processes can also be thermal processes which serve a further purpose, for example for producing component structures in the wafer. Such thermal processes are for example thermal processes for activating dopants after a dopant implantation, thermal processes for indiffusion of dopant atoms into the wafer, or thermal processes for the targeted oxidation of component structures.

In addition, the irradiation process and the thermal processes for producing the vacancy-oxygen centers or for stabilization do not have to take place in close temporal succession. Thus, there is in particular the possibility of the irradiation process being carried out at an early stage by the wafer or basic material manufacturer and one or thermal processes being carried out at a later stage by the component manufacturer that fabricates individual components from the wafer. In this case, as already explained, the thermal processes can be incorporated into fabrication processes of the component manufacturer and can be thermal processes that are required anyway for component production. There is then no need for any additional dedicated processes for the formation of the vacancy-oxygen centers at the wafer that has been irradiated by the wafer manufacturer and thus already prepared for component production. The sole additional method step by comparison with conventional methods then consists in the irradiation of the wafer with high-energy particles.

The duration of the first thermal process, in which the wafer is heated to temperatures of between 700° C. and 1100° C., can be between one hour and more than 20 hours. The temperature is preferably between 780° C. and 1020° C., wherein preferably one or two temperature plateaus at different temperatures are set.

One embodiment provides for the wafer, during the first thermal process, firstly being heated to a temperature of between 780° C. and 810° C. for a first time duration, which is shorter than 10 hours, and subsequently being heated to a temperature of between 980° C. and 1020° C. for a second time duration, which is longer than 10 hours. The first time duration is 5 hours, for example, while the second time duration is 20 hours, for example.

Optionally there is the possibility of carrying out, before the “high-temperature method”, in which the wafer 100 is heated to temperatures of between 700° C. and 1100° C., a “low-temperature process” at lower temperatures of between 350° C. and 450° C. and with a duration of between 5 hours and 20 hours. This low-temperature step is suitable for forming stable nucleation seeds for oxygen precipitates. The thermal steps for producing the low-precipitate zone preferably take place in an inert gas atmosphere.

In the method explained, the maximum of the vacancy concentration produced by the particle irradiation in the semiconductor wafer can be set comparatively exactly by means of the irradiation conditions, that is to say in particular by means of the type of particles used and the irradiation energy with which the particles are radiated in.

FIG. 1D qualitatively shows the vacancy distribution in the semiconductor wafer 100 in the course of an irradiation of the wafer with high-energy particles via the rear side 102 of said wafer. In this case, the maximum vacancy concentration lies in the so-called end-of-range region of the irradiation. That is the region as far as which the irradiation particles penetrate into the wafer 100 proceeding from the rear side 102. In FIG. 1D, a designates the distance from the rear side 102 of the wafer, and a1 designates the distance of the maximum vacancy concentration proceeding from the rear side 102. This positional of the maximum vacancy concentration is dependent on the irradiation energy and, in the case of a proton implantation with an implantation energy of 2.5 MeV, lies in the range between 55 and 60 μm proceeding from the rear side 102. The irradiation with protons can be effected in particular perpendicular or else at an angle of inclination with respect to the rear side 102, for example at an angle of between 5° and 10°.

Given a proton implantation dose of 10¹⁴ cm², the maximum vacancy concentration lies in the end-of-range region at approximately 7·10¹⁸ vacancies/cm³. In the semiconductor region which is arranged between the end-of-range region and the rear side and through which the protons are radiated, the vacancy concentration given the implantation dose mentioned above lies in the region of approximately 5·10¹⁷ vacancies/cm³.

The dimensions of the low-precipitate semiconductor zone 103 in a vertical direction of the wafer are likewise dependent on the irradiation conditions, in particular the irradiation energy. In the method explained, the low-precipitate semiconductor zone 103 arises in the region in which no additional vacancies are produced by the particle irradiation. In this case, the vacancy reduction in the first semiconductor region can take place all the more effectively during the first thermal process, the smaller the dimensions of the first semiconductor region 103 in a vertical direction or the higher the vacancy concentration in the second semiconductor region and the larger the vertical extent of the second semiconductor region 104. The particle irradiation is preferably effected in such a way that the end-of-range region of the irradiation lies as near as possible to the low-precipitate semiconductor zone 103 which is to be produced and which adjoins the front side 101. Customary irradiation energies lie in the range of 2 . . . 5 . . . 10 MeV given wafer thicknesses of between 400 . . . 700 . . . 1000 μm. However, lower irradiation energies such as e.g. in the range of 70-200 KeV are also conceivable in order to produce precipitate-rich zones in the semiconductor crystal. Such irradiation energies can be achieved by commercially available implantation apparatuses.

Before carrying out the particle irradiation, the wafer can optionally be subjected to a second thermal process, in which the wafer is heated to temperatures of greater than 1000° C. in a moist and/or oxidizing atmosphere. Such a procedure is known from EP 0769809 A1, mentioned in the introduction, and serves for injecting interstitial silicon atoms into the wafer in a targeted manner, wherein the depth to which said silicon atoms are injected is dependent on the duration of the thermal process and is all the greater, the longer said thermal process is carried out. The injection of said interstitial silicon atoms leads, in particular in the regions of the semiconductor wafer that are near the surface, already to a reduction of vacancies, in particular to a reduction of vacancy agglomerates, and eliminates so-called D defects in the semiconductor wafer. The preheating treatment of the semiconductor wafer by means of the second thermal process can serve, in particular, for producing identical “initial states” of a plurality of wafers processed by the method explained, in order thereby to produce wafers having identical properties under identical method conditions. This procedure is based on the insight that individual wafers cut off from different single crystals can differ with regard to their vacancy concentrations and with regard to the so-called D defect distributions. As a result of this procedure, in particular prior precipitates can be resolved and the vacancy concentration in the semiconductor crystal treated in this way can be lowered, thereby greatly reducing the probability of precipitate formation during subsequent high-temperature steps.

Since such identical defined starting conditions are desirable in particular in the region of the later low-precipitate semiconductor zone, it suffices, during this preheating treatment, for the front side 101 to be exposed to a moist and/or oxidizing environment, wherein if necessary the penetration depth of the interstitial silicon atoms can also be restricted to the vertical extent of the semiconductor zone 103. It goes without saying, however, that there is also the possibility of both sides 101, 102 of the wafer being exposed to a moist and/or oxidizing atmosphere during this preheating treatment.

Optionally, there is additionally the possibility, after or before carrying out the first thermal process, by means of which the nucleation centers and oxygen agglomerates are produced, of subjecting the wafer to a further thermal process, in which at least the first semiconductor zone 103 is heated in such a way that oxygen atoms outdiffuse from said first semiconductor zone via the front side 101 of the wafer. The temperatures in this further thermal process lie for example in the range between 900° C. and 1250° C. This further thermal process further reduces the oxygen concentration in the low-precipitate semiconductor zone 103, which further reduces the probability of oxygen precipitates arising in said semiconductor zone during subsequent thermal processes. Furthermore, the oxygen reduction in the low-precipitate semiconductor zone reduces the risk of so-called thermal donors arising. Such thermal donors can arise in a crystal lattice when interstitial oxygen is present and during thermal processes at temperatures of between 400° C. and 500° C.

All of the thermal processes explained above can be realized as conventional furnace processes in which the wafer is heated to the desired temperature in a furnace. Furthermore, the thermal processes can also be carried out as RTA processes (RTA=rapid thermal annealing) in which the wafer is heated for example by means of a lamp or a laser beam.

In order to produce the crystal defects in the second semiconductor zone 104′ there is additionally the possibility of carrying out a plurality of implantation steps with different implantation energies. In this case, there is additionally the possibility of carrying out a plurality of first thermal processes in such a way that between two implantation processes a first thermal process is carried out at the temperatures stated.

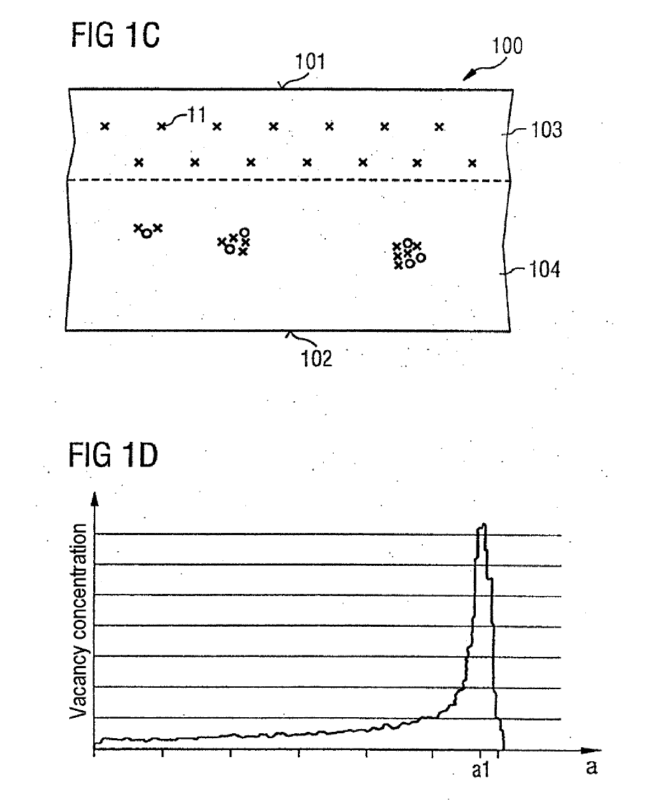

Referring to FIG. 2, there is the possibility of introducing trenches 110 into the semiconductor body proceeding from the rear side 102 before the particle irradiation is carried out. During the subsequent irradiation step, the high-energy particles penetrate into the second semiconductor region 104 of the wafer both via the rear side 102 and via the trenches 110. The trenches afford a further possibility of influencing the penetration depth of the high-energy particles into the semiconductor wafer 100.

Apart from carrying out a particle irradiation in order to produce lattice vacancies in the second semiconductor region 104, there is also the possibility, in order to produce said vacancies, of subjecting the semiconductor wafer to a thermal process in which the rear side 102 of the wafer is exposed to a nitriding atmosphere, while the front side is protected from such a nitriding atmosphere, for example by applying an oxide. The thermal process in the nitriding atmosphere brings about production of lattice vacancies in the second semiconductor region 104, wherein the vacancy concentration that can be achieved is lower, however, than in the particle irradiation explained above. During the thermal process for producing these vacancies, the wafer is preferably heated rapidly, for example by means of an RTA step, and then cooled down comparatively slowly, which is explained in U.S. Pat. No. 6,849,119 B2, mentioned in the introduction. The production of lattice vacancies by means of a thermal process in a nitriding atmosphere is suitable in particular in conjunction with the production of trenches 110 proceeding from the rear side 102 of the semiconductor wafer as explained with reference to FIG. 2.

The method for producing a low-precipitate semiconductor zone as explained above is also suitable for producing a low-precipitate semiconductor zone in the semiconductor substrate of an SOI substrate. As is known, such an SOI substrate has a semiconductor substrate, an insulation layer arranged on the semiconductor substrate, and a semiconductor layer arranged on the insulation layer. Such a substrate can be produced e.g. by a layer arrangement with the insulation layer and the semiconductor layer being bonded onto the semiconductor substrate by means of a wafer bonding method. In this case, the semiconductor substrate can be a CZ wafer, in particular.

An insulation layer 302 and a semiconductor layer 301, which supplement the CZ wafer to form an SOI substrate, are illustrated by dashed lines in FIG. 1A. By means of the method explained above it is possible to produce a low-precipitate semiconductor zone in the wafer 100 in a region adjoining the insulation layer 302. This procedure is particularly advantageous if an electric field is built up during operation of the component in that region of the SOI substrate which adjoins the insulating layer. Hitherto said region has had to be embodied as an epitaxially deposited semiconductor layer in order that e.g. the reverse current caused by generation is kept within tolerable limits that are afforded close tolerances. By virtue of the method explained, the production of this complicated and expensive epitaxial layer can be dispensed with, or such an epitaxial layer can at least be made significantly thinner and thus more cost-effectively than has been customary heretofore.

Furthermore, the semiconductor zone 301 present above the insulation layer 302 can also be produced as a low-precipitate zone of a CZ basic material by application of the method explained. For this purpose, a further CZ semiconductor wafer comprising the later zone 301 is subjected to the method explained, such that a low-precipitate zone adjoining a surface of the wafer arises. This further wafer is then bonded onto the semiconductor substrate, wherein the low-precipitate zone of the further wafer faces the substrate 100 or the insulation layer 302. A precipitate-rich zone (not illustrated) of said further wafer is removed again after wafer bonding e.g. by grinding and/or etching.

Wafer bonding methods themselves are known in principle, and so no further explanations are necessary in this respect. In such a method, two semiconductor surfaces to be bonded are applied to one another, one or else both of which can be oxidized, wherein a thermal process is subsequently carried out in order to bond the two surfaces. Customary temperatures for this lie in the range between 400° C. and 1000° C.

The method explained can also be combined very well with the so-called SIMOX technologies for producing an SOI substrate. In other words, firstly the low-precipitate zone 103 is produced by means of the method explained and then the insulation layer is produced in said zone 103 by means of an oxygen implantation.

The semiconductor wafer, which has a precipitate-free or at least low-precipitate semiconductor zone 103 after the treatment explained in the region of its front side 101, is suitable in particular for realizing vertical power components, as will also be explained below. The wafer can have a basic doping, for example an n-type basic doping, which is produced as early as in the course of pulling the single crystal during the Czochralski method. The low-precipitate semiconductor zone 103 can serve in particular for realizing a semiconductor zone that takes up a reverse voltage of the power component.

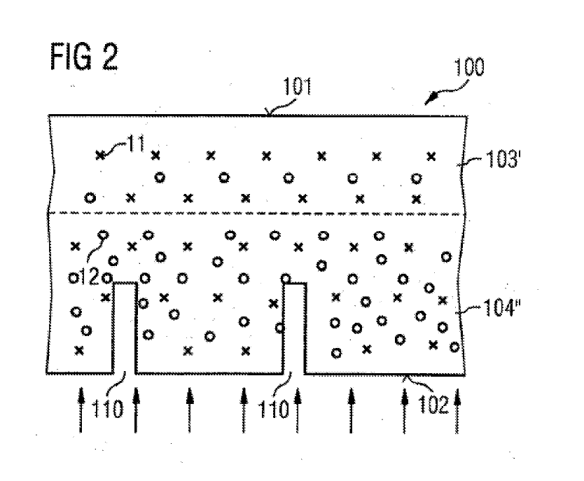

A method for producing an n-doped semiconductor zone in the low-precipitate semiconductor zone 103 of the CZ wafer 100 is explained below with reference to FIGS. 3A to 3C. This method can additionally be employed for producing an n-type basic doping during the pulling of the single crystal, but can also be employed for producing an n-doped semiconductor zone in an undoped CZ wafer, which zone acts like a basically doped zone, that is to say has an approximately constant doping in a vertical direction at least over a large part of its vertical extent. This last is advantageous in particular because the production of a basic doping of the wafer during the pulling of the single crystal leads to unsatisfactory results, in particular to an inhomogeneous and poorly reproducible doping, on account of the oxygen precipitates present.

Referring to FIG. 3A, this method provides for implanting protons into the low-precipitate semiconductor zone 103 of the wafer 100 via the front side 101. In this case, the implantation direction can run perpendicular to the front side 101, but can also run at an angle with respect to said front side 101. The proton implantation firstly causes crystal defects in that region of the low-precipitate semiconductor zone 103 through which protons are radiated. Furthermore, the proton implantation introduces protons into the low-precipitate semiconductor zone 103. In this case, the dimensions of a zone which has crystal defects and through which protons are radiated, in a vertical direction proceeding from the front side 101, are dependent on the implantation energy. In this case, the dimensions of said zone are all the larger, the higher the implantation energy, that is to say the more deeply the protons penetrate into the wafer 100 via the front side 101.

The proton irradiation is followed by a thermal process in which the wafer 100 is heated to temperatures of between 400° C. and 570° C. at least in the region of the zone irradiated with protons, whereby hydrogen-induced donors arise from the crystal defects produced by the proton irradiation and the protons introduced. The temperature during said thermal process preferably lies in the range between 450° C. and 550° C.

By means of the proton implantation, the protons are principally introduced into the end-of-range region of the irradiation. The position of this region proceeding from the front side 101 is dependent on the implantation energy. The end-of-range region forms the “end” of the region irradiated by the proton implantation in a vertical direction of the wafer 100. As already explained, the formation of hydrogen-induced donors presupposes the presence of suitable crystal defects and the presence of protons. The duration of the thermal process is preferably chosen such that the protons principally introduced into the end-of-range region diffuse to an appreciable extent in a direction of the front side 101, in order thereby to produce an n-type doping that is as homogeneous as possible in the irradiated region of the low-precipitate semiconductor zone 103. The duration of this thermal process is between 1 hour and 10 hours, preferably between 3 and 6 hours.

The result of the thermal process, referring to FIG. 3B, is an n-doped semiconductor zone 105 in the low-precipitate semiconductor zone 103 of the wafer 100. Proceeding from the front side 101, the n-type semiconductor zone 105 extends as far as a depth dO into the wafer 100, wherein said depth is dependent on the implantation energy in the manner explained.

FIG. 3C shows an example of a doping profile of said n-type semiconductor zone 105. FIG. 3C plots the doping concentration proceeding from the front side 101. In this case, n_{D0} designates the basic doping of the wafer 100 before the doping method is carried out.

As can be gathered from FIG. 3C, the n-type semiconductor zone 105 proceeding from the front side 101 has an approximately homogeneous doping profile with a doping concentration N_{D}, which rises to a maximum doping concentration N_{Dmax} in an end region of the n-type semiconductor zone 105 and then falls to the basic doping N_{D0}. The end region of the n-type semiconductor zone in which the doping firstly rises and then falls to the basic doping results from the end-of-range region of the proton implantation into which the majority of the protons are incorporated during the implantation. On account of the thermal process, a large portion of the protons diffuses in a direction of the front side 101, which results in the homogeneous doping N_{D} in the region through which the protons are radiated. The protons which diffuse into the depth of the semiconductor in a direction of the rear side 102 do not lead to the formation of donors in this region since no implantation-inducted crystal defects, necessary for forming donors, are present there. The difference between the maximum doping concentration N_{Dmax} in the end-of-range region and the homogeneous doping concentration N_{D} in the irradiated region is crucially dependent on the temperature during the thermal process and the duration of the thermal process. It holds true here that for the same duration of the thermal process, said difference is all the smaller, the higher the temperature during the thermal process, and that for a given temperature during the thermal process, the difference is all the smaller, the longer the duration of the thermal process. Given a sufficiently high temperature and a sufficiently long duration of the thermal process, said difference can also tend toward zero or become very small.

One exemplary embodiment provides for the thermal process to be chosen such that the n-type semiconductor zone 105 produced by the proton implantation and the subsequent thermal treatment has a region having at least approximately homogeneous doping which extends in a vertical direction of the semiconductor body 100 at least over 60%, better over 80%, of the extent of the n-type semiconductor zone 105, where vertical extent is assumed to be a distance between the surface via which implantation was effected and the so-called end of range of the implantation. In this case, the end of range designates the position at which the proton concentration is highest directly after the implantation. In this context, an “at least approximately homogeneous doping” should be understood to mean that the ratio between maximum doping concentration and minimum doping concentration in the region of homogeneous doping is a maximum of 3. One embodiment provides for said ratio to be a maximum of 2, and further embodiments provide for said ratio to be a maximum of 1.5 or 1.2.

The method explained above for producing the n-doped semiconductor zone 105 in a low-precipitate semiconductor zone of a CZ wafer can be carried out after any desired method for producing such a low-precipitate semiconductor zone.

In addition to the method explained above, in particular the method described in EP 0 769 809 A1, in which a CZ wafer is oxidized in an oxidizing atmosphere at temperatures of between 1100° C. and 1180° C. for a duration of between 2 hours and 5 hours, is suitable for producing a low-precipitate zone. In this case, the oxidation can be effected in a dry or moist atmosphere.

The oxidation can in particular also be effected in an atmosphere of an oxygen-containing gaseous dopant compound, such as e.g. POCl₃. A doped layer that additionally arises during such an oxidation in a region of the wafer that is near the surface is removed after carrying out the oxidation step, as is an oxide layer that forms on the surface.

Such an oxidization method can additionally be combined with the above-explained method comprising an irradiation process and at least one thermal process, by means of the irradiation and thermal process being carried out after the oxidation method has been carried out.

Carrying out the oxidation method, whether as sole method for producing the low-precipitate zone or in combination with the irradiation and thermal process, leads unavoidably to the formation of an oxide layer on the surface of the wafer, which is removed as necessary before carrying out further method steps required for the realization of components in the wafer.

The oxide layer can be removed for example by means of an etching method. However, the oxidation of the wafer surface and the etching of the oxide layer lead to a roughening of the wafer surface to an extent that is unsuitable at least for the further production of integrated circuits (ICs). After the oxide layer has been removed, the surface of the wafer is therefore preferably polished before further method steps, for example the method steps for producing the n-doped zone 105 and/or method steps for realizing components, are carried out.

The semiconductor zone 105 produced by means of the method explained above and having an n-type doping with hydrogen-induced donors is suitable in particular for realizing a semiconductor zone of a power semiconductor component that takes up a reverse voltage. Such a zone is for example the drift zone of a MOSFET, the drift zone or n-type base of an IGBT or the drift zone or n-type base of a diode.

The n-type semiconductor zone 105 can in particular also be produced in such a way that the maximum of the doping concentration lies in the region 104 having oxygen agglomerates, such that the low-precipitate zone 103 acquires a homogeneous n-type doping on account of the doping method.

With regard to the treatment method explained with reference to FIGS. 1A to 1C it should be added that in this method no hydrogen-induced donors are formed when protons are used as high-energy particles, since the temperatures of between 700° C. and 1100° C. that are employed during this method are too high for the production of hydrogen-induced donors.

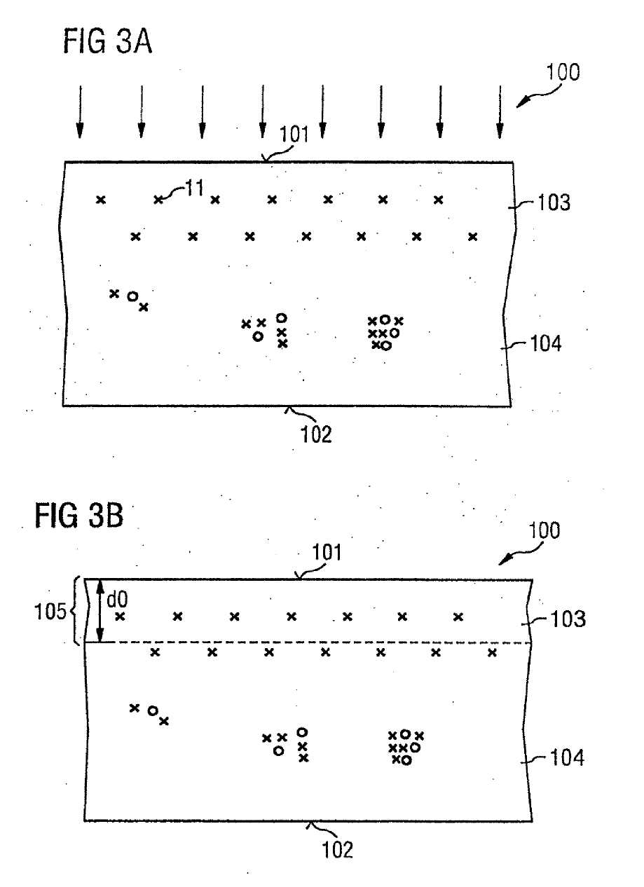

In order to prepare the wafer 100 for the production of power semiconductor components, it is optionally possible, referring to FIG. 4, to produce a monocrystalline epitaxial layer 200 on the front side 101 above the low-precipitate semiconductor zone 103. The doping concentration of said epitaxial layer 200 is preferably adapted to the doping concentration of the low-precipitate semiconductor zone 103 or of the n-doped semiconductor zone 105 present in the low-precipitate semiconductor zone 103 and furthermore to the requirements made of the component. The doping concentration of the epitaxial layer 200 is set in a known manner during the method for depositing said epitaxial layer or else optionally by means of proton irradiation in combination with a suitable heat treatment in accordance with the method explained above.

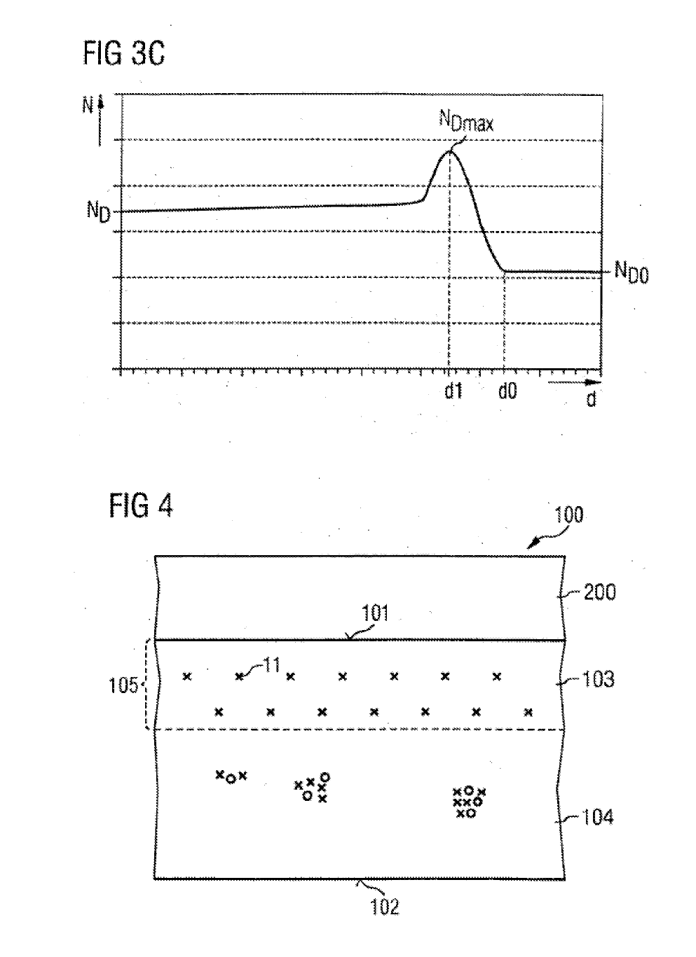

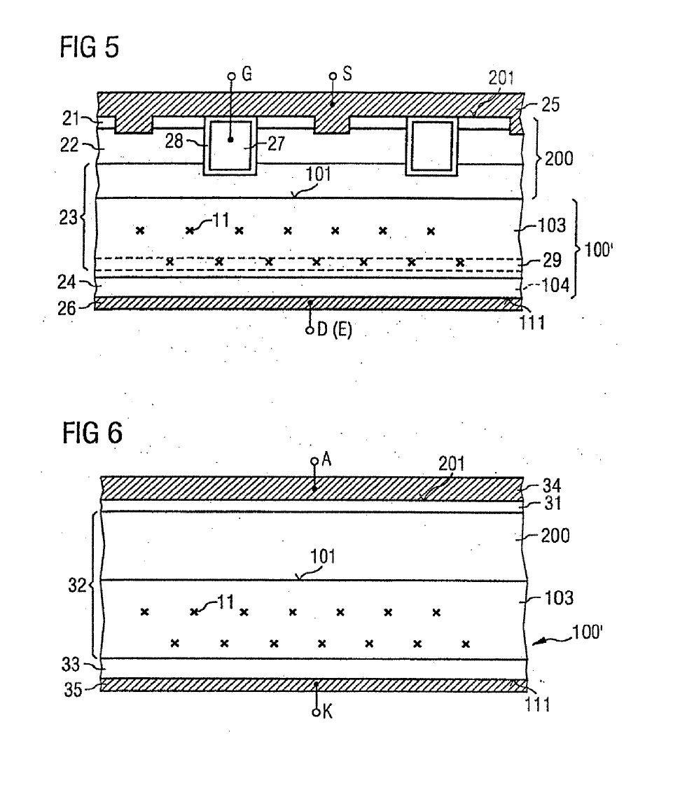

The semiconductor wafer 100 processed by means of the treatment methods explained above is suitable for producing vertical power semiconductor components, which is explained below with reference to FIGS. 5 and 6.

The starting material for the power semiconductor components is formed by the wafer 100, to which an epitaxial layer 200 explained with reference to FIG. 4 can optionally be applied. The presence of such an epitaxial layer 200 is assumed for the explanation below. However, it should be pointed out that said epitaxial layer 200 can also be dispensed with, particularly when the low-precipitate semiconductor zone 103 has in a vertical direction of the wafer 100 a sufficiently large dimension for realizing active component zones, in particular for realizing component zones of the power semiconductor component that take up a reverse voltage.

FIG. 5 shows in side view in cross section a vertical power MOSFET that was produced on the basis of a CZ wafer 100 treated according to the method explained above. The MOSFET has a semiconductor body formed by a section 100′ of the treated wafer (100 in FIGS. 1 to 4) and in the example by an epitaxial layer 200 applied to the wafer. In the example, the reference symbol 201 designates a front side of the epitaxial layer, which simultaneously forms the front side of the semiconductor body. In a manner not illustrated more specifically, the wafer section 100′ was produced by removal of the wafer 100 proceeding from the rear side (reference symbol 102 in FIGS. 1 to 4) of said wafer. The reference symbol 111 designates that surface of said wafer section 100′ which is present after the removal and which simultaneously forms the rear side of the semiconductor body.

In the example, the MOSFET is embodied as a vertical trench MOSFET and has a source zone 21, a body zone 22 adjoining the source zone 21 in a vertical direction, a drift zone 23 adjoining the body zone 22 in a vertical direction, and also a drain zone 24 adjoining the drift zone 23 in a vertical direction. The source zone 21 and the body zone 22 are arranged in the epitaxial layer 200 in the component illustrated in FIG. 5.

For controlling an inversion channel in the body zone a gate electrode 27 is present, of which two electrode sections are illustrated in FIG. 5 and which is arranged in a trench extending into the semiconductor body in a vertical direction proceeding from the front side 201. The gate electrode 27 is dielectrically insulated from the semiconductor body by means of a gate dielectric 28, usually an oxide layer. The source and body zones 21, 22 can be produced in a known manner by means of implantation and diffusion steps. The gate electrode is produced by etching the trench, applying a gate dielectric layer in the trench and depositing an electrode layer in the trench.

Contact is made with the source zone 21 by means of a source electrode 25, which extends in sections in a vertical direction of the semiconductor body right into the body zone 22 in order thereby to short-circuit the source zone 21 and the body zone 22 in a known manner. Contact is made with the drain zone 24 by means of a drain electrode 26 applied to the rear side 111.

The drift zone 23 of the MOSFET is formed in sections by the epitaxial layer 20 and in sections by the low-precipitate semiconductor zone 103 of the wafer section 100′. The drain zone 24 is a semiconductor zone which is highly doped in comparison with the drift zone and which can be produced for example by implantation of dopant atoms via the rear side 111. In this case, the drain zone 24 can be arranged completely in the low-precipitate semiconductor zone 103, but can also be arranged in a section—which remained after the etching back or grinding back—of the semiconductor zone (reference symbol 104 in FIGS. 1 to 3), containing oxygen agglomerates. In this case, what is crucial for proper functioning of the component is that the drift zone, which serves to take up a reverse voltage present when the component is turned off, is formed only by sections of the low-precipitate semiconductor zone 103. Otherwise, oxygen agglomerates present in the drift zone 23 would degrade the performance of the component, in particular the dielectric strength and leakage current behavior thereof.

The dielectric strength of the power MOSFET illustrated is crucially dependent on the dimensions of the drift zone 23 in a vertical direction and furthermore on the doping concentration of said drift zone. The wafer section 100′ that remains after grinding back the wafer during the component production method can exclusively comprise the low-precipitate semiconductor zone 103 produced previously, but can also comprise sections of the zone having oxygen agglomerates 104 in the region of the rear side 102, wherein said zone having oxygen agglomerates is then permitted to serve only for realizing the highly doped drain zone 24 and not for realizing the drift zone 23 that takes up a reverse voltage.

The application of an epitaxial layer 200 can be dispensed with particularly when the dimensions of the low-precipitate semiconductor zone 103 in a vertical direction are sufficiently large for realizing a drift zone with a thickness that is sufficient for a desired dielectric strength.

The vertical power MOSFET illustrated is an n-type power MOSFET, in particular. In this case, the source zone 21, the drift zone 23 and the drain zone 24 are n-doped, while the body zone 22 is p-doped. It goes without saying that on the basis of the wafer treated by means of the method explained above it is also possible to realize a p-type power MOSFET, the component zones of which are doped complementarily in comparison with an n-type power MOSFET.

The doping of the drift zone 23 can be produced in accordance with the method explained above by means of a proton implantation into the wafer front side and a subsequent heat treatment step. These steps for doping the drift zone 23 are preferably effected only after the production of the source and body zones 21, 22 and of the gate oxide 28, since these production steps require temperatures lying far above 600° C., such that a proton-induced doping would disappear. By contrast, production steps requiring temperatures of below approximately 430° C.—such as e.g. the heat treatment of the metallization or of deposited polyimide layers—can be effected later, that is to say after the doping of the drift zone 23. In this case, the thermal budget of the subsequent production steps can be taken into account in the thermal budget during the heat treatment of the proton-induced doping of the drift zone 23. Such a further heat treatment can then be carried out in a correspondingly shorter manner or even be completely obviated.

On the basis of the treated wafer basic material is also possible to realize bipolar power components, such as a trench IGBT for example. The structure of such a trench IGBT corresponds to the structure of the vertical power MOSFET illustrated in FIG. 5, with the difference that an emitter zone 24 doped complementarily to the drift zone 23 is present instead of a drain zone 24 having the same conduction type as the drift zone 23.

In the case of an IGBT, a field stop zone 29 can be disposed upstream of the emitter zone 24 in the drift zone 23, which field stop zone is of the same conduction type as the drift zone 23 but doped more highly than the drift zone 23. Said field stop zone 29 can adjoin the emitter zone 24, but can also be arranged at a distance from the emitter zone 24. However, the field stop zone 29 lies nearer to the emitter zone 24 than to the body zone 22.

The production of such a field stop zone 29 in the CZ wafer 100 can be effected by means of a proton implantation and a subsequent thermal step. In this case, the proton implantation can be effected in particular via the rear side 102 of the wafer 100. In this case, the distance between the field stop zone 29 and the rear side is dependent on the implantation energy used. In order to be able to set the dimensions of the field stop zone in a vertical direction of the wafer 100 and the resulting doping profile, there is the possibility of using different implantation energies, wherein the implantation dose preferably decreases as the implantation energy increases.

The method for producing the field stop zone differs from the method for producing the semiconductor zone having the n-type basic doping 105 by virtue of the duration and/or temperature of the thermal step. When producing the n-type zone 105 the intention is to achieve a diffusion of the protons to an appreciable extent in a direction of the implantation side in order to obtain a doping that is as homogeneous as possible over a region that is as wide as possible in a vertical direction. In contrast to this, the field stop zone 29 is intended to be delimited as exactly as possible in the vertical direction. In order to achieve this, the temperature and/or the duration of the thermal step for producing the field stop zone 29 is lower than the temperature and/or duration when producing the n-type zone 105. The temperature of the thermal process when producing the field stop zone 29 lies for example in the range between 350° C. and 400° C., and the duration of the thermal process is between 30 minutes and 2 hours.

As an alternative, the field stop zone can be implemented completely or at least partly during the method steps for producing the n-type basic doping. As explained, in order to produce the n-type basic doping, protons are implanted into the wafer via the front side 101. The said protons subsequently diffuse from the end-of-range region under the influence of the thermal process in a direction of the front side. This diffusion process can be set by way of the duration and the temperature of the thermal process such that a higher doping arises in the end-of-range region than the n-type basic doping in the intermediate region located between the end-of-range region and the front side. The temperature and/or the duration of the thermal process for producing an n-type basic doping whilst simultaneously producing a field stop zone are lower than in the process for exclusively producing the n-type basic doping. It goes without saying that the implantation energy of the proton irradiation should be set such that the penetration depth of the protons is smaller than the wafer thickness of the wafer.

An additional doping of the field stop zone can be achieved by means of the method explained above in which a proton implantation is carried out via the rear side.

The drift zone 23 is usually n-doped in the case of an IGBT. The body zone and the emitter zone 22, 24 are correspondingly p-doped. An n-doped field stop zone 29 can be produced for example by proton implantation via the rear side 111 or via the rear side 102 of the wafer that has not yet been removed, and a subsequent thermal process at temperatures of between 350° C. and 420° C. and particularly preferably in the temperature range between 360° C. and 400° C.

The basic doping of the drift zone 23 is also preferably produced in the manner explained by means of a proton implantation in combination with a suitable heat treatment step, wherein the proton implantation is preferably effected via the front side 201. Alternatively or supplementary, however, said proton implantation can also be effected via the wafer rear side 111, to be precise particularly preferably after a rear-side thinning process has been carried out.

FIG. 6 shows in side view in cross section a vertical power diode realized on the basis of the treated wafer basic material. In FIG. 6, the reference symbol 201 designates the front side of a semiconductor body in which the diode is integrated, while the reference symbol 111 designates a rear side of said semiconductor body. The semiconductor body comprises a wafer section 100′ obtained by grinding back the wafer 100 explained with reference to FIGS. 1 to 3. The epitaxial layer 200 explained with reference to FIG. 4 is optionally applied to said wafer section 100′.

The power diode has in the region of the front side 201 a p-type emitter zone or anode zone 31, a base zone 32 adjoining the p-type emitter zone, and also an n-type emitter zone or cathode zone 33 adjoining the base zone 32 in a vertical direction. The base zone 32 is either p- or n-doped and serves to take up the reverse voltage present when the power diode is operated in the reverse direction. In the example, the base zone 32 is formed by a section of the epitaxial layer 200 and by a section of the low-precipitate semiconductor zone 103 of the wafer section 100′. The n-type emitter 33 can likewise be formed completely in the low-precipitate semiconductor zone 103. Said n-type emitter is produced for example by implantation of n-type dopant atoms via the rear side 111. However, the n-type emitter 33 can also be formed in sections by the semiconductor zone (reference symbol 104 in FIGS. 1 to 3) of the wafer that has oxygen agglomerates. What is crucial, however, is that the base zone 32 that takes up the reverse voltage is formed only by low-precipitate semiconductor zones 103 of the wafer.

Contact is made with the anode zone 31 of the diode by means of an anode electrode 34, which forms an anode terminal A. Contact is made with the cathode zone 33 by means of a cathode electrode 35, which forms a cathode terminal K.

### LIST OF REFERENCE SYMBOLS

11 Oxygen atoms
12 Vacancy
21 Source zone
22 Body zone
23 Drift zone
24 Drain zone, emitter zone
25 Source electrode
26 Drain electrode, emitter electrode
27 Gate electrode
28 Gate dielectric
31 p-type emitter
32 Base
33 n-type emitter
34, 35 Terminal electrode
100 Semiconductor wafer
100′ Wafer section after removal of the wafer
101 Front side of the semiconductor wafer
102 Rear side of the semiconductor wafer
103 Low-precipitate semiconductor zone of the wafer
103′ First semiconductor region of the wafer
104 Semiconductor zone of the wafer that contains oxygen agglomerates
104′ Second semiconductor region of the wafer
104″ Region of the semiconductor wafer with increased vacancy concentration
110 Trenches
111 Rear side of the removed semiconductor wafer, rear side of a semiconductor body
200 Epitaxial layer
201 Front side of the epitaxial layer, front side of a semiconductor body
A Anode terminal
D Drain terminal
E Emitter terminal
G Gate terminal
K Cathode terminal
S Source terminal What is claimed is:

1.-72. (canceled)

73. A method comprising:
providing an oxygen-containing semiconductor wafer including a first side, a second side opposite the first side, a first semiconductor region adjoining the first side, and a second semiconductor region adjoining the second side;
irradiating the second side of the wafer such that lattice vacancies arise in the second semiconductor region; and
carrying out a first thermal process forming oxygen agglomerates in the second semiconductor region and lattice vacancies diffuse from the first semiconductor region into the second semiconductor region.

74. The method of claim 73, comprising wherein the temperature during the thermal process is between 780° C. and 1020° C.

75. The method of claim 73, comprising:
heating the wafer to a first temperature during the thermal process for a first time duration; and
heating the wafer to a second temperature greater than the first temperature for a second time duration, which is longer than the first time duration.

76. The method of claim 73, comprising:
before irradiating the second side of the wafer, carrying out a second thermal process, and exposing at least the first side to a moist and/or oxidizing atmosphere.

77. The method of claim 73, comprising producing trenches which extend into the wafer proceeding from the second side.

78. A method comprising:
providing an oxygen-containing semiconductor wafer including a first side, a second side opposite the first side, a first semiconductor region adjoining the first side, and a second semiconductor region adjoining the second side, wherein a low-vacancy semiconductor zone is formed in the first semiconductor region;
irradiating the second side of the wafer with protons or helium ions, such that lattice vacancies arise in the second semiconductor region; and
carrying out a first thermal process, wherein the wafer is heated to temperatures of between 700° C. and 1100° C. and the duration of which is chosen such that oxygen agglomerates form in the second semiconductor region and that lattice vacancies diffuse from the first semiconductor region into the second semiconductor region.

79. The method of claim 78, comprising:
heating the wafer, during the thermal process, to a temperature of between 790° C. and 810° C. for a first time duration, which is shorter than ten hours; and
heating to a temperature of between 985° C. and 1015° C. for a second time duration, which is longer than ten hours.

80. The method of claim 78, comprising:
before irradiating the second side of the wafer, carrying out a second thermal process, wherein the wafer is heated to a temperature of greater than 1000° C., and wherein at least the first side is exposed to a moist and/or oxidizing atmosphere.

81. The method of claim 78, comprising after irradiating the second side of the wafer and before the first thermal process:
carrying out a further thermal process, wherein the wafer is heated to temperatures of between 350° C. and 450° C.

82. The method of claim 78, comprising producing, before irradiating the wafer, trenches which extend into the wafer proceeding from the second side.

83. The method of claim 78, comprising:
carrying out a third thermal process, wherein at least the first semiconductor zone is heated in such a way that oxygen atoms outdiffuse from said first semiconductor zone via the first side of the wafer.

84. The method of claim 78, comprising:
after carrying out the first thermal process, producing an n-doped semiconductor zone in the first semiconductor zone;
irradiating the wafer with protons via at least one of the first and second sides, thus giving rise to crystal defects in the first semiconductor zone; and
carrying out a further thermal process, wherein the wafer is heated to temperatures of between 400° C. and 570° C. at least in the region of the first side, such that hydrogen-induced donors arise.

85. The method of claim 78, comprising choosing the duration and the temperature of the further thermal process such that the n-doped semiconductor zone has in a vertical direction of the semiconductor body at least over 60% of its vertical extent an at least approximately homogeneous doping produced by the proton irradiation.

86. The method of claim 85, comprising choosing the duration and the temperature of the further thermal process such that the n-doped semiconductor zone has in a vertical direction of the semiconductor body at least over 80% of its vertical extent an at least approximately homogeneous doping produced by the proton irradiation.

87. The method of claim 78, comprising:
after carrying out the second thermal process, producing an n-doped semiconductor zone in the first semiconductor zone;
irradiating the wafer with protons via at least one of the first and second sides, thus giving rise to crystal defects in the first semiconductor zone; and
carrying out a further thermal process, in which the wafer is heated to temperatures of between 400° C. and 570° C. at least in the region of the first side, such that hydrogen-induced donors arise.

88. The method of claim 78, wherein irradiating the wafer with protons comprises at least two irradiation processes wherein the wafer is irradiated with protons having a different irradiation energy.

89. The method of claim 78, comprising:
the production of an n-doped field stop zone in the wafer;
irradiating the wafer with protons via at least one of the first and second sides, thus giving rise to crystal defects in the first semiconductor zone; and
carrying out a thermal process wherein the wafer is heated to temperatures of between 350° C. and 550° C., such that a field stop zone with hydrogen-induced donors arises.

90. The method of claim 89, comprising effecting the proton irradiation for producing the field stop zone via the second side, and heating the wafer to temperatures of between 350° C. and 420° C.

91. The method of claim 89, comprising employing a plurality of irradiation steps with a plurality of irradiation energies for the production of the field stop zone.

92. A method for producing an n-doped zone in a semiconductor wafer comprising:
a first side;
a second side opposite the first side; and
a first semiconductor zone low in oxygen precipitates and adjoining the first side, comprising:
implanting protons into the wafer via the first side, thus giving rise to crystal defects in the first semiconductor zone and whereby protons are implanted right into an end-of-range region—dependent on an implantation energy—within the semiconductor wafer;
carrying out a further thermal process, wherein the wafer is heated to temperatures of between 400° C. and 570° C. at least in the region of the first side, such that an n-doped semiconductor zone with hydrogen-induced donors arises, and wherein the duration and the temperature are chosen such that protons diffuse from the end-of-range region in a direction of the first side, such that the n-doped semiconductor zone has a region of at least approximately homogeneous doping which extends in a vertical direction of the semiconductor body at least over 60% of a distance between the end-of-range region and the first side and which has an at least approximately homogeneous doping produced by the proton implantation, such that a ratio between maximum doping concentration and minimum doping concentration in the region of homogeneous doping is a maximum of 3.

93. The method of claim 92, comprising choosing the duration and the temperature of the further thermal process such that the region of at least approximately homogeneous doping extends over 80% of a distance between the end-of-range region and the first side.

94. A vertical power semiconductor component comprising:
a semiconductor body having a semiconductor substrate produced according to the Czochralski method, wherein the semiconductor substrate has a semiconductor zone low in oxygen precipitates; and
a component zone designed to take up a reverse voltage when the component is driven in the off state and arranged at least in sections in the semiconductor zone low in oxygen precipitates, and has an n-type basic doping formed by hydrogen-induced donors.

95. The semiconductor component of claim 94, comprising wherein the semiconductor body has an epitaxial layer applied to the semiconductor substrate, and wherein the zone which takes up the reverse voltage is arranged in sections in the epitaxial layer.

96. The semiconductor component of claim 94, comprising a MOSFET or an IGBT having a drift zone, forming the zone which takes up the reverse voltage.

97. The semiconductor component of claim 94, comprising a thyristor or a diode having an n-type base, forming the zone which takes up the reverse voltage.
